(19) United States
(12) Patent Application Publication
(10) Pub. No.: US 2021/0391226 A1
(43) Pub. Date: Dec. 16, 2021

(54) SEMICONDUCTOR DEVICE PACKAGES HAVING CAP WITH INTEGRATED ELECTRICAL LEADS

(71) Applicant: STMICROELECTRONICS, INC., Calamba City (PH)

(72) Inventors: Rennier RODRIGUEZ, Bulacan (PH); John Alexander SORIANO, Muntinlupa (PH); Aaron CADAG, Calamba (PH)

(73) Assignee: STMICROELECTRONICS, INC., Calamba City (PH)

(21) Appl. No.: 17/346,766

(22) Filed: Jun. 14, 2021

Related U.S. Application Data
(60) Provisional application No. 63/039,165, filed on Jun. 15, 2020.

(51) Int. Cl. H01L 23/043; H01L 21/48; H01L 21/52; H01L 23/495

(52) U.S. Cl. CPC H01L 23/043; H01L 21/4821; H01L 23/49531; H01L 23/49541; H01L 21/52

(57) ABSTRACT

One or more embodiments are directed to semiconductor device packages having a cap with integrated metal interconnects or conductive leads. One embodiment is directed to a semiconductor device package that includes a cap having a cover extending along a first direction and sidewalls extending from the cover along a second direction that is transverse to the first direction. A plurality of electrical leads are disposed on inner surfaces of the sidewalls and extend over lower surfaces of the sidewalls. A semiconductor die is attached to an inner surface of the cover of the cap, and the semiconductor die is electrically coupled to the plurality of electrical leads.

### BACKGROUND

### Technical Field

Embodiments of the present disclosure are directed to semiconductor device packages, and more particularly, to semiconductor device packages having a cap and one or more conductive interconnects or electrical leads.

### Description of the Related Art

Semiconductor packages or semiconductor device packages typically include a carrier such as a substrate or lead frame on which a semiconductor die is positioned and attached. A casing or cap covers the semiconductor die and is attached to the carrier. In this way, the semiconductor die may be packaged within the cap, which covers the die, and the carrier, which forms a floor beneath the die.

Semiconductor device packages typically further include electrical leads which are exposed, for example, at a bottom surface of the carrier. The leads are electrically coupled to the semiconductor die within the package and facilitate communication between the semiconductor die and external circuitry. Semiconductor device packages come in many forms, including ball grid array (BGA) packages, land grid array (LGA) packages, and quad flat no-lead (“QFN”) packages.

### BRIEF SUMMARY

In various embodiments, the present disclosure provides semiconductor packages in which a semiconductor die is secured to an upper inner surface of a cap. Conductive interconnects or leads are formed in the interior of the cap and extend along inner sidewalls of the cap between the upper inner surface and a lower surface of the cap. The conductive interconnects are exposed at the lower surface of the cap and may be electrically coupled, for example, to external circuitry such as a printed circuit board (PCB) or the like. The semiconductor die is secured to the upper inner surface of the cap with an active surface of the die facing away from the upper inner surface of the cap. Electrical leads or wire bonds are formed between the active surface of the semiconductor die and the conductive interconnects on the upper inner surface of the cap. Since the semiconductor die is secured to the inside or inner surface of the cap, an additional carrier may be omitted and the cap can be bonded directly to external circuitry, such as a PCB.

In one or more embodiments, a semiconductor device package is provided that includes a cap having a cover extending along a first direction and sidewalls extending from the cover along a second direction that is transverse to the first direction. A plurality of electrical leads are disposed on inner surfaces of the sidewalls and extend over lower surfaces of the sidewalls. A semiconductor die is attached to an inner surface of the cover of the cap, and the semiconductor die is electrically coupled to the plurality of electrical leads.

In one or more embodiments, a method is provided that includes: forming a cap for a semiconductor device package, the cap including a cover extending in a first direction and sidewalls extending from the cover in a second direction that is transverse to the first direction; forming a plurality of electrical leads on inner surfaces of the sidewalls and extending over lower surfaces of the sidewalls of the cap; and attaching a semiconductor die to an inner surface of the cover of the cap.

In one or more embodiments, an electronic device is provided that includes a microprocessor and a semiconductor device package electrically coupled to the microprocessor. The semiconductor device package includes a cap having a cover extending along a first direction and sidewalls extending from the cover along a second direction that is transverse to the first direction. A plurality of electrical leads are disposed on inner surfaces of the sidewalls and extend over lower surfaces of the sidewalls. A semiconductor die is attached to an inner surface of the cover of the cap, and the semiconductor die is electrically coupled to the plurality of electrical leads.

### BRIEF DESCRIPTION OF THE SEVERAL VIEWS OF THE DRAWINGS

FIG. 1A is a perspective view of a semiconductor device package, in accordance with one or more embodiments of the present disclosure.

FIG. 1B is a cross-sectional view of the semiconductor device package of FIG. 1A.

FIG. 2A is a perspective view of a cap with conductive interconnects and a die pad which may be included in various semiconductor device packages, in accordance with one or more embodiments.

FIG. 2B is a cross-sectional view of a semiconductor device package including the cap of FIG. 2A.

FIG. 3A is a perspective view of a cap with conductive interconnects and an opening which may be included in various semiconductor device packages, in accordance with one or more embodiments.

FIG. 3B is a cross-sectional view of a semiconductor device package including the cap shown in FIG. 3A, in accordance with one or more embodiments.

FIGS. 4A through 4D illustrate a method of manufacturing a semiconductor device package, such as the semiconductor device package shown in FIGS. 1A and 1B, in accordance with one or more embodiments.

FIG. 5 is a flowchart illustrating another method of manufacturing a semiconductor device package, such as the semiconductor device package 10 shown in FIGS. 1A and 1B, in accordance with one or more embodiments.

FIG. 6 illustrates an electronic device including a semiconductor device package, in accordance with one or more embodiments.

### DETAILED DESCRIPTION

In the following description, certain specific details are set forth in order to provide a thorough understanding of various disclosed embodiments. However, one skilled in the relevant art will recognize that embodiments may be practiced without one or more of these specific details, or with other methods, components, materials, etc. In other instances, well-known structures associated with semiconductor devices and packages have not been shown or described in detail to avoid unnecessarily obscuring descriptions of the various embodiments provided herein.

Unless the context requires otherwise, throughout the specification and claims that follow, the word “comprise” and variations thereof, such as “comprises” and “comprising” are to be construed in an open, inclusive sense, that is, as “including, but not limited to.” Further, the terms “first,” second,” and similar indicators of sequence are to be construed as being interchangeable unless the context clearly dictates otherwise.

Reference throughout the specification to “one embodiment” or “an embodiment” means that a particular feature, structure, or characteristic described in connection with the embodiment is included in at least one embodiment. Thus, the appearance of the phrases “in one embodiment” or “in an embodiment” in various places throughout the specification are not necessarily all referring to the same embodiment. Furthermore, the particular features, structures, or characteristics may be combined in any suitable manner in one or more embodiments of the present disclosure.

As used in the specification and the appended claims, the singular forms “a,” “an,” and “the” include plural referents unless the context clearly dictates otherwise. It should also be noted that the term “or” is generally employed in its broadest sense, that is, as meaning “and/or” unless the context clearly dictates otherwise.

The present disclosure is directed to integrating components in a semiconductor device package without the need for a separate carrier for a semiconductor die. More particularly, the present disclosure provides various devices and methods in which a cap includes a plurality of conductive interconnects or leads and a semiconductor die is secured to an inner surface of the cap and electrically coupled to the leads.

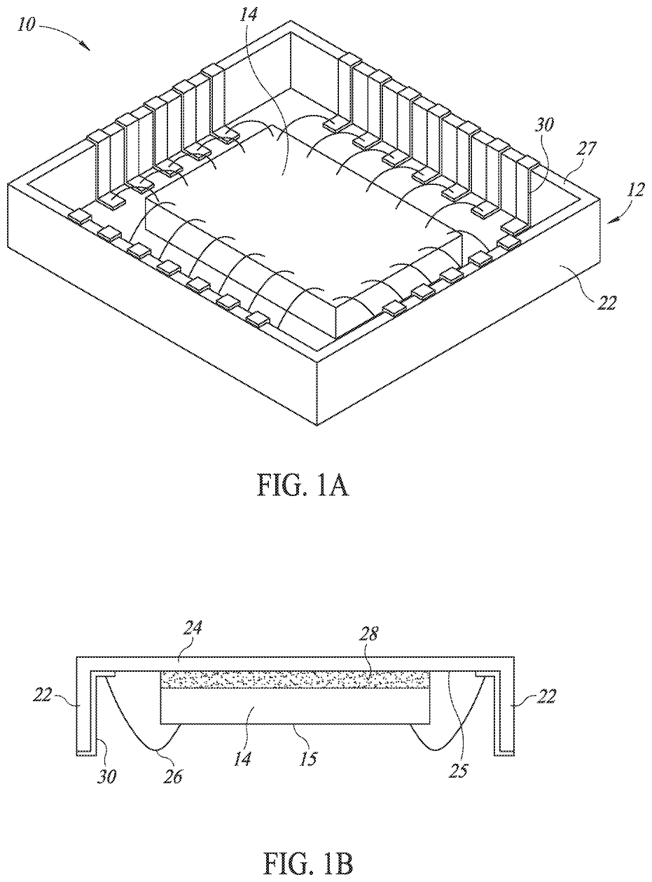

FIGS. 1A and 1B illustrate a semiconductor device package 10, in accordance with one or more embodiments of the present disclosure. The semiconductor device package 10 includes a semiconductor die 14 secured to a cap 12.

The cap 12 includes sidewalls 22 and a cover 24. As shown in FIG. 1B, the cover 24 may form an upper or top portion of the semiconductor device package 10. The sidewalls 22 extend downward from the cover 24. The cover 24 may extend along a first direction (e.g., the horizontal direction as shown in FIG. 1B) and the sidewalls 22 extend along a second direction that is transverse to the first direction (e.g., in the vertical direction as shown in FIG. 1B). In some embodiments, the sidewalls 22 extend along a direction that is substantially perpendicular to the cover 24. In some embodiments, the sidewalls 22 are disposed along a perimeter of the cap 12. The cap 12 thus defines an interior space between the lateral sidewalls 22 and the cover 24.

The semiconductor die 14 is disposed within the interior space of the cap 12. More particularly, in some embodiments, the semiconductor die 14 is physically secured to an inner upper surface 25 of the cap 12 and positioned between the sidewalls 22. In some embodiments, the semiconductor die 14 is attached to the inner upper surface 25 of the cap 12 by an adhesive 28. The adhesive 28 may be any material suitable to securely attach the semiconductor die 14 to the inner upper surface 25 of the cap 12. In some embodiments, the adhesive 28 may be glue. In some embodiments, the adhesive 28 may be a die attach film. In some embodiments, the adhesive 28 may be any adhesive material, such as a paste, epoxy, film, tape or the like.

The semiconductor die 14 may be any semiconductor die including one or more electrical components, such as integrated circuits. The semiconductor die 14 is made from a semiconductor material, such as silicon, and includes an active surface 15 in or on which various integrated circuits are formed. The integrated circuits may be analog or digital circuits implemented as active devices, passive devices, conductive layers, and dielectric layers formed within the semiconductor die 14 and electrically interconnected according to the electrical design and function of the semiconductor die 14.

The semiconductor device package 10 includes a plurality of electrical leads 30 disposed at least partially in the interior of the cap 12. The leads 30 may be any conductive interconnects and may be formed of any conductive material. In some embodiments, the leads 30 are formed of copper.

The leads 30 may be at least partially disposed on the inner upper surface 25 of the cap 12. The leads 30 extend along inner surfaces of the sidewalls 22 between the inner upper surface 25 and a lower surface 27 of the cap 12. The lower surface 27 of the cap 12 is an exposed lower surface of the sidewalls 22 which may be, for example, positioned on another structure such as a PCB or other substrate. The leads 30 may be provided on each of the sidewalls 22 of the cap 12 in some embodiments, and in other embodiments, the leads 30 may be provided on only some of the sidewalls 22 of the cap 12. As shown in FIGS. 1A and 1B, portions of the leads 30 may be exposed at the lower surface 27 of the cap 12 and the leads 30 may be electrically coupled, for example, to external circuitry such as a printed circuit board (PCB) or the like.

In some embodiments, the semiconductor die 14 may be secured to the inner upper surface 25 of the cap 12 with the active surface 15 of the die facing away from the inner upper surface 25 of the cap 25, for example, as shown in FIG. 1B. Electrical wires or wire bonds 26 are formed between the active surface 15 of the semiconductor die 14 and the electrical leads 30. The wire bonds 26 electrically couple circuitry, such as input/output circuitry, of the semiconductor die 14 to corresponding leads 30. In some embodiments, the wire bonds 26 extend from the active surface 15 of the semiconductor die 14 to portions of the leads 30 disposed on the inner upper surface 25 of the cap 12. However, embodiments of the present disclosure are not limited thereto, and in various embodiments, the wire bonds 26 may extend from the active surface 15 of the semiconductor die 14 to portions of the leads disposed on inner surfaces of the sidewalls 22 of the cap 12. The wire bonds 26 may be formed of any electrically conductive material, and in some embodiments, the wire bonds 26 are formed of copper.

While the active surface 15 of the semiconductor die 14 is illustrated in FIGS. 1A and 1B as facing away from the inner upper surface 25 of the cap 12, in various embodiments, the semiconductor die 14 may be secured to the cap 12 with the active surface 15 facing the inner upper surface 25 of the cap 12. For example, in some embodiments, the semiconductor die 14 may be electrically and mechanically coupled to the cap 12 by flip chip bonding, with solder or other electrically conductive material forming an electrical and mechanical bond between the active surface 15 of the semiconductor die 14 and corresponding leads 30 on the inner upper surface 25 of the cap 12.

The cap 12 may be formed of any rigid or semi-rigid material, such as a plastic material. In some embodiments, the cap 12 is formed of an electrically or thermally insulating material. In some embodiments, the cap 12 is formed of a thermoset polymer or a ceramic material.

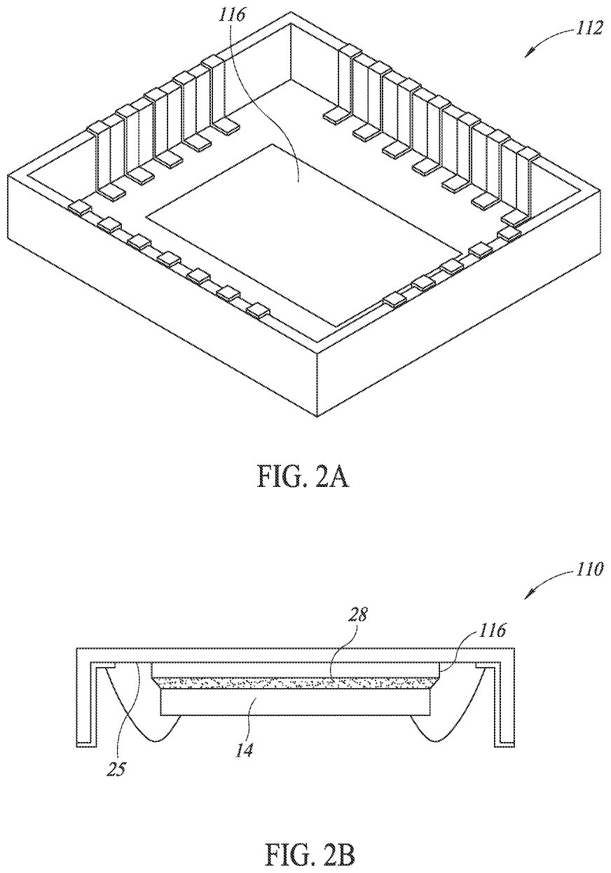

FIG. 2A is a perspective view of a cap 112 with conductive interconnects and a die pad which may be included in various semiconductor device packages, in accordance with one or more embodiments. FIG. 2B is a cross-sectional view of a semiconductor device package 110 including the cap 112 of FIG. 2A.

The cap 112 and the semiconductor device package 110 shown in FIGS. 2A and 2B is similar in structure and in function to the cap 12 and the semiconductor device package 10 shown in FIGS. 1A and 1B, except for the differences discussed herein. The features shared by the semiconductor device packages 110 and 10 will not be described herein again in the interest of brevity. The key difference between the semiconductor packages 110 and 10 is that the semiconductor device package 110 further includes a die pad 116.

The die pad 116 may be formed directly on the inner upper surface 25 of the cap 112, for example, by deposition or the like. In some embodiments, the die pad 116 is attached to the inner upper surface 25 by any suitable adhesive, such as glue or the like.

In some embodiments, the die pad 116 may be formed of any thermally conductive material and may serve to dissipate heat from the interior of the cap 112, such as heat generated by the semiconductor die 14. In some embodiments, the die pad 116 is formed of a metal, such as copper.

The semiconductor die 14 may be attached to the die pad 116 by an adhesive 28. The adhesive 28 may be any material suitable to securely attach the semiconductor die 14 to the die pad 116, such as glue, die attach film, or any adhesive material, such as a paste, epoxy, film, tape or the like.

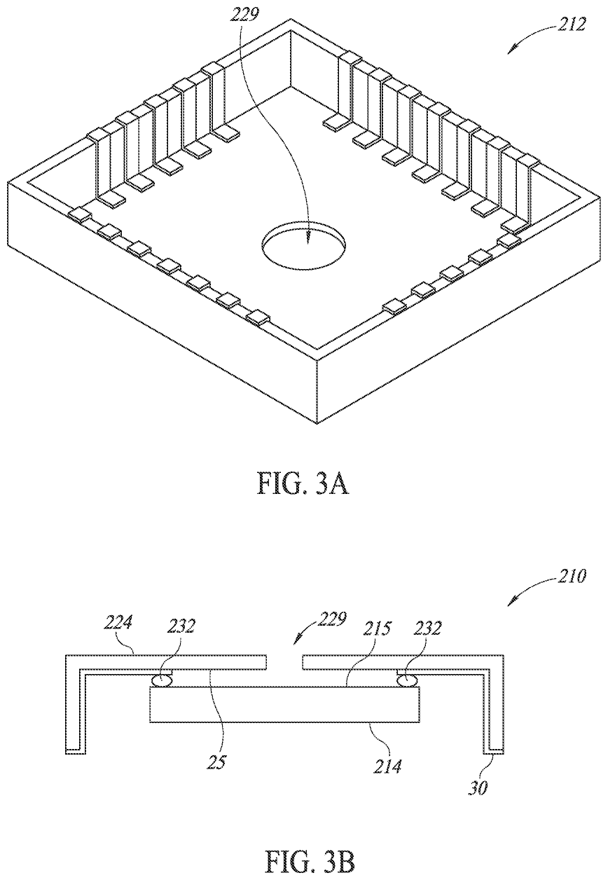

FIG. 3A is a perspective view of a cap 212 with conductive interconnects and an opening which may be included in various semiconductor device packages, in accordance with one or more embodiments. FIG. 3B is a cross-sectional view of a semiconductor device package 210 including the cap shown in FIG. 3A, in accordance with one or more embodiments.

The cap 212 and the semiconductor device package 210 shown in FIGS. 3A and 3B is substantially similar in structure and in function to the cap 12 and the semiconductor device package 10 shown in FIGS. 1A and 1B, except for the differences that will be discussed herein. The features shared by the semiconductor device packages 210 and 10 will not be described herein again in the interest of brevity.

A key difference between the semiconductor device packages 210 and 10 is that the cap 212 of the semiconductor device package 210 includes an opening 229 that extends through the cover 224 of the cap 212. The opening 229 fluidically couples an interior of the semiconductor device package 210 and the cap 212 with an exterior environment. For example, the opening 229 may provide a path through which ambient air, pressure, temperature, or any other characteristic of the external environment may be transmitted or otherwise fluidically connected to the interior space of the cap 212 and of the semiconductor device package 210.

Another difference between the semiconductor device packages 210 and 10 is that the semiconductor die 214 of the semiconductor device package 210 is mechanically and electrically coupled to the cap 212 via flip chip bonding. For example, as shown in FIG. 3B, solder 232 or any other suitable electrically conductive material may be disposed between the active surface 215 of the semiconductor die 214 and the electrical leads 30. The solder 232 may form electrical and mechanical bonds between the active surface 215 of the semiconductor die 214 and the corresponding leads 30 on the inner upper surface 25 of the cap 212. In some embodiments, the solder 232 may be reflowed to complete the electrical interconnection between the circuitry at the active surface 215 of the semiconductor die 214 and the corresponding leads 30 on the cap 212.

The opening 229 may have various different shapes or sizes in various embodiments, and the shape or size of the opening 229 may be selected based on design considerations for the semiconductor device package 210. For example, in some embodiments, the opening 229 may be one or more through-holes formed through a central portion of the cover 224 of the cap 212. The opening 229 may be formed by any method for forming an opening or through-hole in the cover 224, for example, by etching, punching, drilling, or the like, through the cover 224 of the cap 212. In some embodiments, two or more openings 229 may be included in the cap 212.

The semiconductor device package 210 may be any semiconductor device package in which the semiconductor die 214 is exposed to the external environment. For example, in some embodiments, the semiconductor device package 210 may be a pressure sensor and may include a semiconductor die 214 for pressure sensing applications. The semiconductor die 214 may include a diaphragm configured to sense pressure, and the diaphragm may be located at the active surface 215 of the semiconductor die 214. As such, the diaphragm of the semiconductor die 214 may be in fluid communication with the external environment via the opening 239, which facilitates sensing of external pressures or the like. In various embodiments, the semiconductor die 214 may include a sensor for sensing any attributes of the external environment, such as temperature, humidity, sound, or any other attributes.

In some embodiments, the semiconductor device package 210 may be an optical semiconductor device package and may include a semiconductor die 214 for optical sensing applications. For example, the semiconductor die 214 may include a light emitting device and a light receiving device, and the cap 212 may include a respective opening 229 aligned with each of the light emitting and light receiving devices of the semiconductor die 214. As such, light may be emitted by the light emitting device through an opening 229 of the cap 212 and the emitted light may be reflected by an object in the external environment and received through another opening 229 of the cap 212 that is aligned with the light receiving device. One example of such a semiconductor device package that includes a light emitting and a light receiving device is a time of flight sensor device package. However, embodiments of the present disclosure are not limited thereto, and in various embodiments, the semiconductor device package may include any semiconductor die 214 that is configured to sense one or more attributes or parameters of an external environment via the opening 229, or to emit or receive radiation such as light through the opening 229.

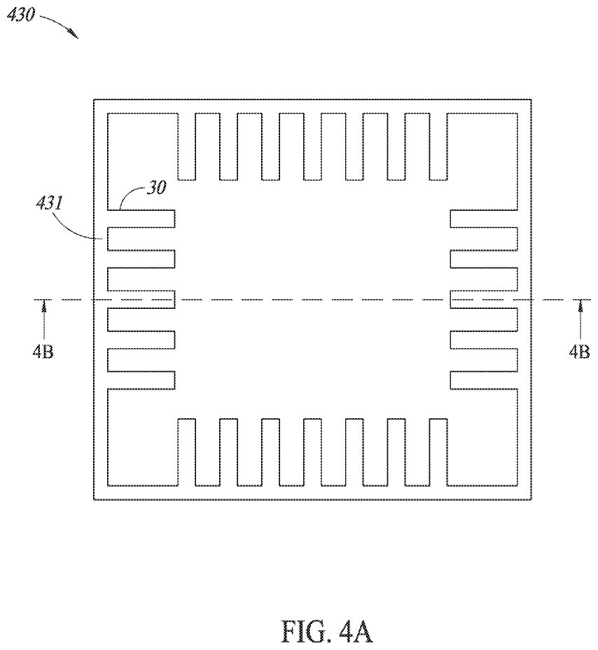

FIGS. 4A through 4D illustrate a method of manufacturing a semiconductor device package, such as the semiconductor device package 10 shown in FIGS. 1A and 1B.

As shown in FIG. 4A, a lead frame 430 is provided or manufactured. The lead frame 430 may be any suitable lead frame, and in various embodiments, the lead frame 430 may be manufactured from copper, aluminum, gold, or any other conductive material. In some embodiments, the lead frame 430 is formed by a masking and etching process. For example, a sheet of conductive material may be masked, and the mask may correspond to the shape of the lead frame 430 shown in FIG. 4A. The unmasked portions of the sheet of conductive material may be selectively removed, for example, by etching. The mask may then be removed, leaving behind only the defined lead frame 430 as shown in FIG. 4A.

The lead frame 430 includes a plurality of edges 431 which may be bars or strips of the conductive material of the lead frame 430, and which form an outer perimeter or sides of the lead frame 430. A plurality of leads 30 extend inwardly from the edges 431 and are spaced apart from one another. The plurality of leads 30 are connected to the edges 431. A plurality of leads 30 may extend from each of the edges 431. For example, as shown in FIG. 4A, five leads 30 may extend inwardly from each of the edges 431. However, this is shown for illustrative purposes only, and in various embodiments, more or fewer than five leads 30 may extend inwardly from each of the edges 431.

As shown in FIG. 4B, the leads 30 are shaped to have an upper portion 30a, a sidewall portion 30b, and a lower portion 30c. The cross-sectional view of 4B is taken along the line 4B-4B of Figure A after the leads 30 have been shaped from the lead frame 430. The upper portion 30a and the lower portion 30c extend along a first direction (e.g., along the horizontal direction as shown in FIG. 4B), and the sidewall portion 30b extends along a second direction that is transverse to the first direction (e.g., along the vertical direction as shown in FIG. 4B).

The leads 30 may be shaped by any suitable technique, including, for example, by stamping or pressing the leads 30 in a mold to form the upper portion 30a, sidewall portion 30b, and lower portion 30c. In various embodiments, the leads 30 may be shaped to have any desired shape or design. As shown in FIG. 4B, portions of the edges 431 may remain connected to the lower portion 30c of the leads 30.

As shown in FIG. 4C, the cap 12 is formed on the leads 30. The cap 12 may be formed by any suitable method or technique, including, for example, by a molding process. As one example, the lead frame 430, including the shaped leads 30, may be placed in mold cavity having a desired shape for the cap 12, and the cap 12 may be formed by injecting or otherwise forcing a molding material into the mold cavity. The molding material may be cured or solidified to form the cap 12. The cap 12 may thus be formed to have any desired shape. In the example shown in FIG. 4C, the cap 12 may be formed to have sidewalls 22 that define an outer perimeter of the cap 12, and a cover 24 that extends between the sidewalls 22. The cap 12 may have a rectangular shape in top plan view; however, any other shapes may be formed for the cap 12 in various embodiments.

The sidewalls 22 of the cap 12 are formed to cover upper surfaces of the lower portion 30c of the leads 30, and the sidewalls 22 extend in the second direction (e.g., the vertical direction as shown in FIG. 4C) along and in contact with the sidewall portion 30b of the leads 30. The cover 24 of the cap 12 covers the upper portion 30a of the leads 30. The cap 12 may be formed in direct contact with each of the upper portion 30a, the sidewall portion 30b, and the lower portion 30c of the leads 30, as shown. Additionally, the leads 30 may be secured to the cap 12, for example, by the molding process. For example, as the cap 12 is cured, the cap 12 may bond with the leads 30 such that the leads 30 are securely attached to the cap 12.

The edges 431 of the lead frame 430 may be removed, as shown in FIG. 4C. The edges 431 may be removed by any suitable process. In some embodiments, the edges 431 are removed after the cap 12 is formed on the leads 30. For example, the edges 431 may be removed by cutting the edges 431 from the lower portion 30c of the leads (e.g., by singulation or the like). Once the edges 431 are removed from the lead frame 430, the leads 30 are spaced apart and electrically isolated from one another.

As shown in FIG. 4D, the semiconductor die 14 is attached to the inner upper surface 25 of the cap 12. The semiconductor die 14 is disposed within the interior space of the cap 12 and physically secured to the inner upper surface 25 of the cap 12 at a position between the sidewalls 22. The semiconductor die 14 may be attached to the inner upper surface 25 of the cap 12 by an adhesive 28.

Wire bonds 26 are formed between the active surface 15 of the semiconductor die 14 and the electrical leads 30. In some embodiments, the wire bonds 26 are formed to extend from the active surface 15 of the semiconductor die 14 to portions of the leads 30 disposed on the inner upper surface 25 of the cap 12. However, embodiments of the present disclosure are not limited thereto, and in various embodiments, the wire bonds 26 may extend from the active surface 15 of the semiconductor die 14 to portions of the leads disposed on inner surfaces of the sidewalls 22 of the cap 12. The wire bonds 26 may be formed of any electrically conductive material, and in some embodiments, the wire bonds 26 are formed of copper.

The completed semiconductor device package 10, as shown in FIG. 4D, may be subsequently electrically or mechanically coupled to an external substrate or circuitry, such as a PCB (not shown). The PCB may include, for example, leads or lead pads which are electrically coupled to the lower portion 30c of the leads 30.

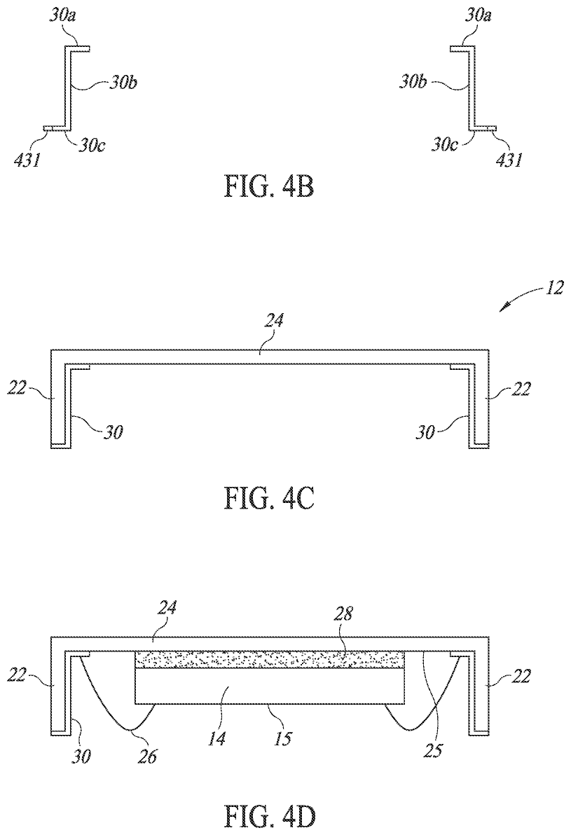

FIG. 5 is a flowchart illustrating another method 500 of manufacturing a semiconductor device package, such as the semiconductor device package 10 shown in FIGS. 1A and 1B.

At 502, the method 500 includes forming a cap 12. The cap 12 may be formed by any suitable method, including, for example, by a molding process. The cap 12 may be formed of any rigid or semi-rigid material, such as a plastic material. In some embodiments, the cap 12 is formed of an electrically or thermally insulating material. In some embodiments, the cap 12 is formed of a thermoset polymer or a ceramic material.

The cap 12 includes sidewalls 22 and a cover 24. The cover 24 may form an upper or top portion of the cap 12, and the sidewalls 22 extend downward from the cover 24. The cover 24 may extend along a first direction (e.g., the horizontal direction as shown in FIG. 1B) and the sidewalls 22 extend along a second direction that is transverse to the first direction (e.g., in the vertical direction as shown in FIG. 1B). The cap 12 thus defines an interior space between the lateral sidewalls 22 and the cover 24.

At 504, the method 500 includes masking the cap 12 to define electrical lead regions. The cap 12 may be masked by any suitable technique, including any lithographic or photolithographic process. In some embodiments, the mask covers portions of the cap 12 at which the electrical leads 30 will not be formed. For example, the unmasked portions of the cap 12 may define regions at which the leads 30 will be formed on the cap 12.

At 506, the method 500 includes forming the electrical leads 30 on the unmasked portions of the cap 12. The electrical leads 30 may be formed by any suitable technique, including by deposition of a conductive material onto the unmasked portions of the cap 12. In some embodiments, the leads 30 are deposited on the lower surfaces of the sidewalls 22 of the cap 12 (e.g., forming the lower portions 30c of the leads 30), on the sidewalls 22 of the cap 12 (e.g., forming the sidewall portions 30b of the leads 30), and on the inner upper surface 25 of the cap 12 (e.g., forming the upper portions 30a of the leads 30).

At 508, the method 500 includes removing the mask to expose inner surfaces of the cap 12. The mask may be removed by any suitable technique, including by etching or by physically peeling or otherwise removing the mask from the cap 12. Once the mask is removed, the cap 12 and leads 30 are complete. The leads 30 are spaced apart from one another and extend from the inner upper surface 25 of the cap 12, along the sidewalls 22 of the cap 12, and along the lower surfaces of the sidewalls 22.

At 510, the method 500 includes attaching the semiconductor die 14 to the inner upper surface 25 of the cap 12 and forming wire bonds 26 between the active surface 15 of the semiconductor die 14 and the electrical leads 30. The semiconductor die 14 is disposed within the interior space of the cap 12 and physically secured to the inner upper surface 25 of the cap 12 at a position between the sidewalls 22. The semiconductor die 14 may be attached to the inner upper surface 25 of the cap 12 by an adhesive 28.

Wire bonds 26 are formed between the active surface 15 of the semiconductor die 14 and the electrical leads 30. In some embodiments, the wire bonds 26 are formed to extend from the active surface 15 of the semiconductor die 14 to portions of the leads 30 disposed on the inner upper surface 25 of the cap 12. However, embodiments of the present disclosure are not limited thereto, and in various embodiments, the wire bonds 26 may extend from the active surface 15 of the semiconductor die 14 to portions of the leads disposed on inner surfaces of the sidewalls 22 of the cap 12. The wire bonds 26 may be formed of any electrically conductive material, and in some embodiments, the wire bonds 26 are formed of copper.

The completed semiconductor device package 10 may be subsequently electrically or mechanically coupled to an external substrate or circuitry, such as a PCB (not shown). The PCB may include, for example, leads or lead pads which are electrically coupled to the lower portion 30c of the leads 30.

While the methods illustrated in FIGS. 4A to 4D and FIG. 5 are described with respect to the semiconductor device package 10 shown in FIGS. 1A and 1B, it will be readily appreciated that the methods may be modified to form various other embodiments provided herein, such as the semiconductor device package 210 shown and described with respect to FIGS. 3A and 3B. For example, the cap 212 and leads 30 may be formed in a similar manner as described with respect to FIGS. 4A to 4D and FIG. 5; however, the cap 212 may further be formed to include one or more openings 229. The openings 229 may be formed by any suitable technique, including by punching or otherwise forming through-holes in the cover of the cap 212.

Moreover, the semiconductor die 214 may be attached to the inner upper surface 25 of the cap 212 by flip chip bonding, as previously described herein.

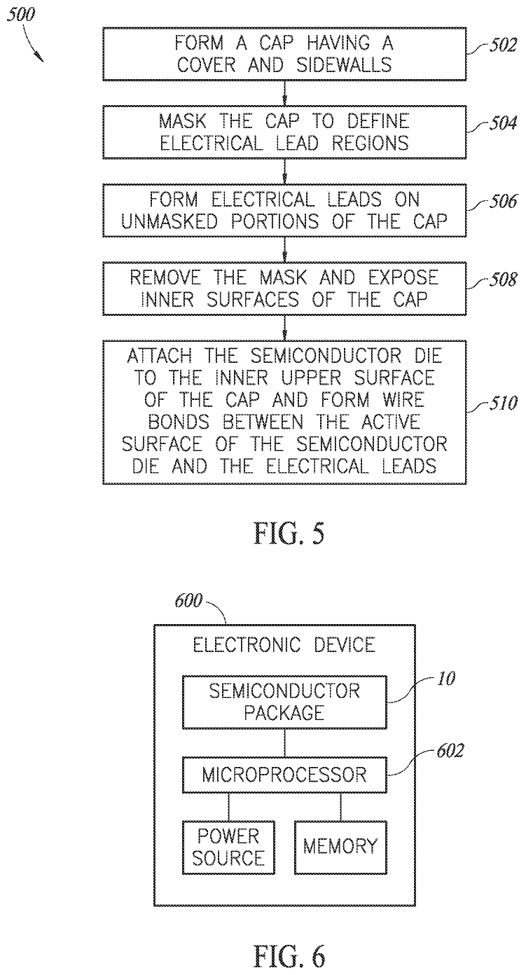

FIG. 6 shows an electronic device 600 including a semiconductor device package described herein, such as the semiconductor package 10, 110, or 210. The semiconductor package 10 is electrically coupled to a microprocessor 602. The microprocessor 602 may be any circuit configured to receive or send electrical signals to the semiconductor package 10. The electronic device 600 may further include a power source 604 configured to provide electric power for the device 600. The power source 604, which may be a battery, may be coupled to the microprocessor 602. The electric device 600 may also include a memory 606 coupled to or incorporated in the microprocessor 602.

In one or more embodiments, the electronic device 600 may be a cell phone, smartphone, tablet, camera, and/or wearable computing device that may be located in clothing, shoes, watches, glasses or any other wearable structures. In some embodiments, the electronic device 600, or the semiconductor package 10 itself, may be located in a vehicle, such as boat and car, a robot, or any other moveable structure or machinery.

While the semiconductor device packages have been described herein as having an open interior space (e.g., a space within the cap into which the semiconductor die is positioned and attached), in some embodiments, the interior space of the cap may be filled, for example, by an encapsulant material such as an epoxy mold compound or the like. In other embodiments, the interior space of the cap remains substantially open, and the package may be connected to an external device, such as a PCB or the like, thereby sealing the interior of the package once connected to the external device.

In various embodiments, the present disclosure provides semiconductor device packages in which a semiconductor die is attached or otherwise secured to an inner surface of an insulative cap. The cap includes conductive interconnects or electrical leads which are electrically coupled to the semiconductor die. The cap can be positioned directly on external circuitry, such as a substrate or PCB, and the leads of the semiconductor device package may be connected to corresponding leads or lead pads of the substrate or PCB. In this way, the semiconductor device package may omit an additional carrier, as the semiconductor die may be attached to the inside of the cap itself. This facilitates significant advantages by way of a reduction of thickness of the semiconductor device package, as well as cost savings and defect reductions due to the omission of an additional carrier.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A semiconductor device package, comprising:
a cap having a cover extending along a first direction and sidewalls extending from the cover along a second direction that is transverse to the first direction;
a plurality of electrical leads on inner surfaces of the sidewalls and extending over lower surfaces of the sidewalls; and
a semiconductor die attached to an inner surface of the cover of the cap, the semiconductor die electrically coupled to the plurality of electrical leads.

2. The semiconductor device package of claim 1, wherein the semiconductor die is attached to the inner surface of the cover of the cap by an adhesive.

3. The semiconductor device package of claim 1, wherein the semiconductor die is attached to the inner surface of the cover of the cap by solder.

4. The semiconductor device package of claim 1, wherein the plurality of electrical leads extend at least partially on the inner surface of the cover of the cap.

5. The semiconductor device package of claim 1, wherein the cover of the cap includes at least one opening.

6. The semiconductor device package of claim 5, wherein the semiconductor die includes at least one sensor in fluid communication with an exterior environment via the at least one opening.

7. The semiconductor device package of claim 6, wherein the at least one sensor includes at least one of a pressure sensor, a temperature sensor, a humidity sensor, a sound sensor, or an optical sensor.

8. The semiconductor device package of claim 1, wherein an active surface of the semiconductor die faces away from the inner surface of the cover of the cap, the semiconductor device package further including a plurality of wires electrically connected between the active surface of the semiconductor die and the plurality of electrical leads.

9. The semiconductor device package of claim 1, wherein each of the plurality of electrical leads includes an upper portion on the inner surface of the cover of the cap, a sidewall portion on the inner surface of a respective sidewall, and a lower portion on the lower surface of the respective sidewall.

10. The semiconductor package of claim 1, further comprising a die pad between the semiconductor die and the inner surface of the cover of the cap.

11. A method, comprising:
forming a cap for a semiconductor device package, the cap including a cover extending in a first direction and sidewalls extending from the cover in a second direction that is transverse to the first direction;
forming a plurality of electrical leads on inner surfaces of the sidewalls and extending over lower surfaces of the sidewalls of the cap; and
attaching a semiconductor die to an inner surface of the cover of the cap.

12. The method of claim 11, further comprising:
electrically coupling the semiconductor die to the plurality of electrical leads.

13. The method of claim 11, wherein the forming the plurality of electrical leads includes:
defining electrical lead regions by forming a mask on the cap;
depositing a conductive material on unmasked portions of the cap; and
forming the plurality of electrical leads by removing the mask and exposing inner surfaces of the cap.

14. The method of claim 11, wherein the forming the plurality of electrical leads includes:
shaping leads of a lead frame, each of the leads shaped to have an upper portion extending along the first direction, a sidewall portion extending along the second direction, and a lower portion extending along the first direction.

15. The method of claim 14, wherein the forming the cap includes molding the cap onto the shaped leads of the lead frame.

16. The method of claim 15, further comprising:
removing edge portions of the lead frame subsequent to the forming the cap.

17. The method of claim 11, wherein the attaching the semiconductor die includes attaching the semiconductor die to the inner surface of the cover of the cap with an adhesive.

18. The method of claim 11, further comprising:
attaching the cap to a printed circuit board, portions of the electrical leads on the lower surfaces of the sidewalls of the cap being electrically and mechanically coupled to corresponding lead pads of the printed circuit board.

19. An electronic device, comprising:
a microprocessor; and
a semiconductor device package electrically coupled to the microprocessor, the semiconductor device package including:
a cap having a cover extending along a first direction and sidewalls extending from the cover along a second direction that is transverse to the first direction;
a plurality of electrical leads on inner surfaces of the sidewalls and extending over lower surfaces of the sidewalls; and
a semiconductor die attached to an inner surface of the cover of the cap, the semiconductor die electrically coupled to the plurality of electrical leads.

20. The electronic device of claim 19, wherein the electronic device is at least one of a cell phone, a smartphone, a tablet computer device, a camera, a wearable computing device, a vehicle, or a robotic machine.
